(19) United States
(12) Patent Application Publication
(10) Pub. No.: US 2014/0152646 A1
(43) Pub. Date: Jun. 5, 2014

(54) CUBIC DISPLAY AND MANUFACTURING METHOD THEREOF

(71) Applicant: Samsung Display Co., Ltd., Yongin-City (KR)

(72) Inventors: Ki-Nyeng Kang, Yongin-City (KR); Mu-Gyeom Kim, Yongin-City (KR)

(73) Assignee: Samsung Display Co., Ltd., Yongin-City (KR)

(21) Appl. No.: 13/937,146

(22) Filed: Jul. 8, 2013

(30) Foreign Application Priority Data
Dec. 5, 2012 (KR) 10-2012-0140483

(51) Int. Cl. G09G 3/20

(52) U.S. Cl. CPC G09G 3/2085
USPC 345/214; 29/829

(57) ABSTRACT

A multisided display device includes a flexible substrate configured to have a shape of a polyhedron and including a plurality of flattened portions, a plurality of bending portions, a first surface having a plurality of pixels thereon, and a second surface opposite the first surface, a plurality of rigid substrates corresponding to the plurality of flattened portions and positioned at the second surface of the flexible substrate, a scan driver for supplying a scan signal to the plurality of pixels, and a data driver for supplying a data signal to the plurality of pixels.

### RELATED APPLICATION

This application claims priority to and the benefit of Korean Patent Application No. 10-2012-0140483 filed in the Korean Intellectual Property Office on Dec. 5, 2012, the entire content of which is incorporated herein by reference.

### BACKGROUND

1. Field

The described technology relates generally to a cubic display device.

2. Description of the Related Art

Recently, while materials of a display device, driving techniques, and processing techniques have been developed, display devices have become thin and lightweight. Also, research on a cubic display device having a display panel that is able to be bent or folded using a flexible substrate has been actively discussed.

Flexible substrates are generally made of a plastic film, such as a polyimide. However, the flexible substrate is weak against moisture penetration, such that long-term reliability is deteriorated in aspects of a display characteristic and a usage life-span.

The above information disclosed in this Background section is intended only for enhancing the reader's understanding of the background of the described technology, and may therefore contain information that does not form the prior art that is already known in this country to a person of ordinary skill in the art.

### SUMMARY

Embodiments of the present invention provide a cubic display device for increasing reliability of a product by increasing display quality and expanding a usage life-span and a manufacturing method thereof.

A multisided display device according to an exemplary embodiment of the present invention includes a flexible substrate configured to have a shape of a polyhedron and including a plurality of flattened portions, a plurality of bending portions, a first surface having a plurality of pixels thereon, and a second surface opposite the first surface, a plurality of rigid substrates corresponding to the plurality of flattened portions and positioned at the second surface of the flexible substrate, a scan driver for supplying a scan signal to the plurality of pixels, and a data driver for supplying a data signal to the plurality of pixels.

The plurality of flattened portions and the plurality of bending portions may collectively have the shape of the polyhedron in an unfolded state, and the flexible substrate may be configured to have the shape of the polyhedron by bending the plurality of bending portions.

The first surface of the flexible substrate may be configured to be toward an inside of the polyhedron, and the pixels may be at areas corresponding to the flattened portions and to the bending portions.

Each of the pixels may include a transparent pixel electrode, an organic emission layer on the pixel electrode, and a reflective common electrode on the organic emission layer, and the pixels may be configured to emit light toward the flexible substrate.

The multisided display device may further include, a barrier layer between the flexible substrate and the pixels, and a thin film encapsulation layer on the pixels.

The thin film encapsulation layer may cover the scan driver or the data driver.

The flexible substrate may further include a bonding portion at an edge of a first one of the flattened portions, and the bonding portion may be configured to overlap and be affixed to an inner surface of a second one of the flattened portions.

The scan driver and the data driver may be at the first surface of the flexible substrate, and may be configured to respectively supply the scan signal and the data signal to at least one of the flattened portions.

One of the scan driver or the data driver may be on the bonding portion, and an other one of the scan driver or the data driver may be on one of the flattened portions or one of the bending portions.

The scan driver and the data driver may be on an area of the bonding portion, and the bonding portion may be at a location corresponding to the rigid substrate.

The multisided display device may further include a plurality of first scan signal lines arranged in a first direction, a plurality of second scan signal lines arranged in a second direction crossing the first direction, and a plurality of data signal lines arranged in the first direction, and the first scan signal lines, the second scan signal lines, and the data signal lines may be between the data driver and the pixels, and the scan driver and the data driver may be arranged in parallel.

The multisided display device may further include an insulating layer between the first scan signal lines and the second scan signal lines, and the second scan signal lines may be electrically coupled to respective ones of the first scan signal lines through via holes in the insulating layer.

The multisided display device may further include a transparent bonding layer between the flexible substrate and the rigid substrate, and the second surface of the flexible substrate may be toward an outside of the polyhedron.

A method manufacturing a multisided display device according to an embodiment of the present invention includes providing a rigid substrate, forming a transparent bonding layer and a flexible substrate on the rigid substrate, forming a plurality of pixels, a scan driver, and a data driver on the flexible substrate, cutting the rigid substrate and the flexible substrate to comprise a plurality of flattened portions, a plurality of bending portions, and a plurality of bonding portions, removing portions of the rigid substrate such that remaining portions of the rigid substrate are at an outer surface of respective ones of the flattened portions, and bending the bending portions to form a polyhedron.

The removing the portions of the rigid substrate may cause the rigid substrate and the flexible substrate to be in a shape of the polyhedron in an unfolded state.

The plurality of pixels, the scan driver, and the data driver may be formed at a first surface configured to face toward an inside of the polyhedron.

The method may further include forming a barrier layer between the flexible substrate and the plurality of pixels, and forming a thin film encapsulation layer on the pixels, and the pixels may be at the flattened portions and the bending portions.

One of the scan driver or the data driver may be at one of the bonding portions, and an other one of the scan driver or the data driver may be at one of the flattened portions or one of the bending portions.

The scan driver and the data driver may be at one of the bonding portions, and the removing the portions of the rigid substrate may cause the remaining portions of the rigid substrate to be at an outer surface of the bonding portions.

The method may further include folding the bonding portion inside one of the flattened portions, and bonding the bonding portion to the one of the flattened portions.

The moisture penetration of the rigid substrate is comparatively reduced such that external moisture penetration into the driving circuit and the organic light emitting diode (OLED) may be effectively reduced or prevented. Accordingly, the multisided display device reduces or minimizes the characteristic change of the driving circuit and the organic light emitting diode (OLED), thereby increasing the display quality and expanding the usage life-span.

### BRIEF DESCRIPTION OF THE DRAWINGS

FIG. 1 is a perspective view of a cubic display device according to a first exemplary embodiment.

FIG. 2 is a top plan view showing an unfolded state of the flexible substrate shown in FIG. 1.

FIG. 3 is a cross-sectional view of a cubic display device taken along the line III-III of FIG. 2.

FIG. 4 is a partial enlarged view of the flexible substrate of the embodiment shown in FIG. 2.

FIG. 5 is an enlarged cross-sectional view of a cubic display device according to a second exemplary embodiment.

FIG. 6 is an enlarged cross-sectional view of a cubic display device according to a third exemplary embodiment.

FIG. 7 is an enlarged cross-sectional view of a cubic display device according to a fourth exemplary embodiment.

FIG. 8 is a view of a pixel circuit of the cubic display device of the embodiment shown in FIG. 1.

FIG. 9 is a partial enlarged cross-sectional view of the cubic display device of the embodiment shown in FIG. 3.

FIG. 10 is a process flowchart of a manufacturing method of a cubic display device according to an exemplary embodiment of the present invention.

FIG. 11 is a cross-sectional view depicting the third step for the cubic display device of the embodiment shown in FIG. 10.

FIG. 12 is a top plan view depicting the fourth step for the cubic display device of the embodiment shown in FIG. 10.

FIG. 13 is a cross-sectional view depicting the fourth step for the cubic display device of the embodiment shown in FIG. 10.

FIG. 14 is a cross-sectional view depicting the fifth step for the cubic display device of the embodiment shown in FIG. 10.

FIG. 15 is a perspective view depicting the sixth step for the cubic display device of the embodiment shown in FIG. 10.

### DETAILED DESCRIPTION

Embodiments of the present invention will be described more fully hereinafter with reference to the accompanying drawings, in which exemplary embodiments of the invention are shown. As those skilled in the art would realize, the described embodiments may be modified in various different ways without departing from the spirit or scope of the present invention.

In the specification, unless explicitly described to the contrary, the word “comprise” and variations thereof, such as “comprises” or “comprising,” will be understood to imply the inclusion of stated elements, but will not be understood to imply the exclusion of any other elements. In addition, when it is said that any part, such as a layer, film, region, or plate is “on” or “positioned on” another part, the part may be directly on the other part, or above the other part, or the part may be below or above the other part with one or more intermediate parts. Further, in the specification, an upper part of a target portion may indicate an upper part or a lower part of a target portion, and does not mean that the target portion is necessarily positioned at an upper side with respect to a direction of gravity.

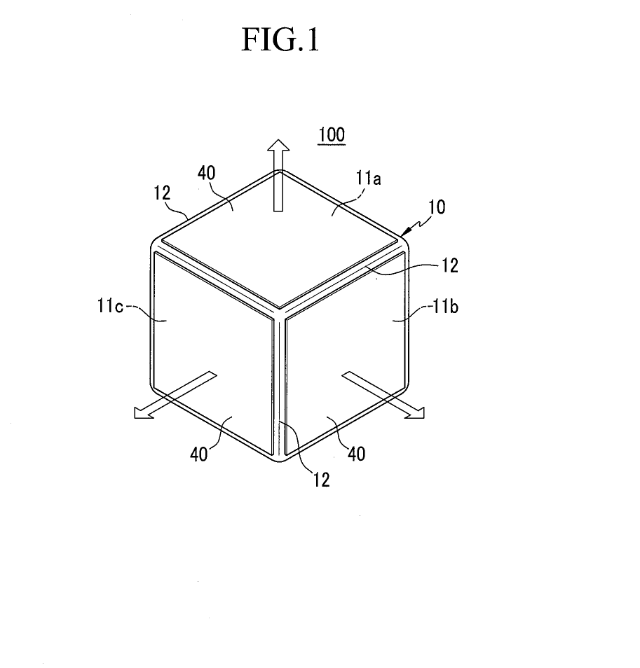

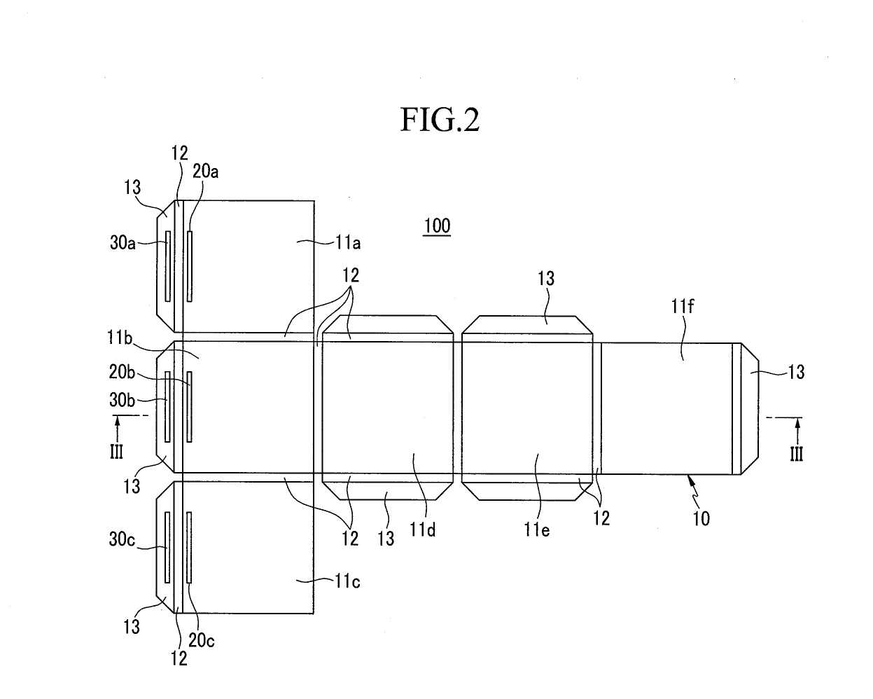

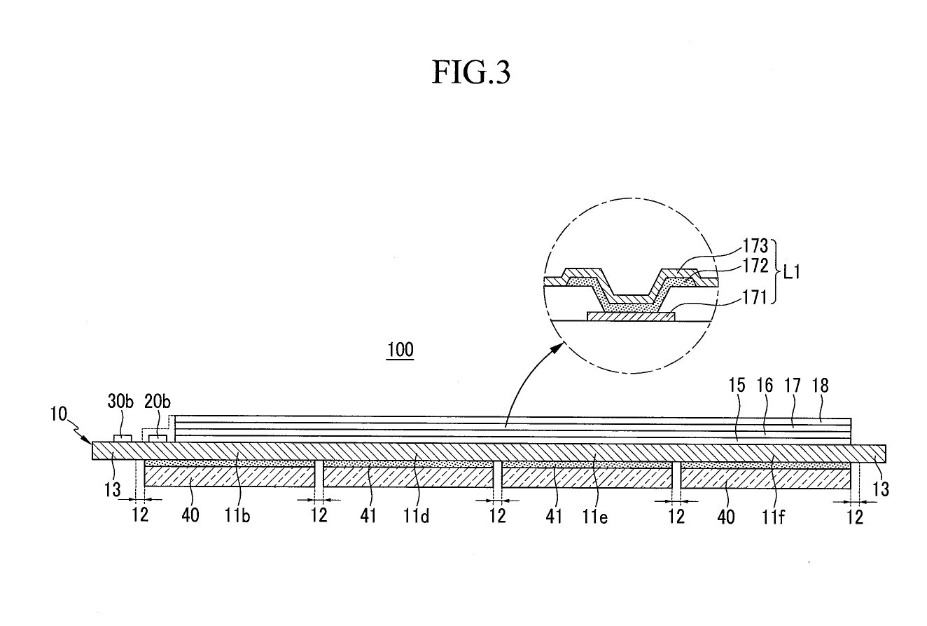

FIG. 1 is a perspective view of a cubic display device according to a first exemplary embodiment of the present invention, FIG. 2 is a top plan view showing an unfolded state of the flexible substrate of the embodiment shown in FIG. 1, and FIG. 3 is a cross-sectional view of a cubic display device taken along the line III-III of FIG. 2.

Referring to FIGS. 1 to 3, the cubic display device 100 is made in a polyhedral shape. For example, other embodiments of the display device may be formed of various shapes, such as a pentagonal, hexahedral, octahedral, polygonal columnar, or polygonal pyramidal shape. FIG. 1 shows an example of the cubic display device 100 made in the hexahedral shape.

The cubic display device 100 includes a flexible substrate 10, as well as a plurality of pixels, scan drivers 20a-20c, and data drivers 30a-30c formed on the flexible substrate 10. The flexible substrate 10 may be formed of a plastic material such as a polyimide, and has a characteristic of being easily bent, such that the flexible substrate 10 is easily bent or folded to thereby form the polyhedral shape. The flexible substrate 10 includes a plurality of flattened portions 11a-11f, and also includes a plurality of bending portions 12.

The flattened portions 11a-11f and the bending portions 12 may be manufactured with an unfolded view shape of the polyhedron. That is, the flexible substrate 10 may be flatly manufactured in accordance with the unfolded view shape of FIG. 2 and including the plurality of flattened portions 11a-11f with one bending portion 12 (that is initially in a flat state) positioned between each of adjacent flattened portions 11a-11f according to one direction (referring to FIG. 2 and FIG. 3). Also, the flexible substrate 10 is deformed for the plurality of flattened portions 11a-11f to form an angle(s) with each other by bending of the bending portions 12, thereby forming the polyhedron.

FIG. 2 shows an example of the flexible substrate 10 in which six flattened portions 11a-11f are arranged with a “T” shape, the bending portions 12 being between respective ones of the flattened portions 11a-11f. In the flexible substrate 10, the number of the flattened portions 11a-11f and the unfolded view shape of the flattened portions 11a-11f and bending portions 12 are not limited to the example shown in FIG. 2, and may be variously changed.

At one surface of the flexible substrate 10, a plurality of thin film transistors and a plurality of organic light emitting diodes (OLED) are continuously formed through the plurality of flattened portions 11a-11f and the plurality of bending portions 12. In FIG. 3, the plurality of thin film transistors are schematically shown by one thin film transistor layer 16, and a plurality of organic light emitting diodes (OLED) are schematically shown by one organic light emitting diode (OLED) layer 17.

In the cubic display device 100, one pixel includes a driving circuit including at least two thin film transistors (a switching transistor and a driving transistor) and at least one capacitor, and an organic light emitting diode (OLED) L1 coupled to the driving transistor.

The organic light emitting diode (OLED) L1 includes a pixel electrode 171 formed on one surface of the flexible substrate 10, an organic emission layer 172 formed on the pixel electrode 171, and a common electrode 173 formed on the organic emission layer 172. Holes and electrons injected from the pixel electrode 171 and the common electrode 173 are combined on the organic emission layer 172 to generate excitons, and the excitons release energy such that light is emitted.

At this time, the pixel electrode 171 is formed of a transparent conductive layer transmitting the light and the common electrode 173 is formed of a metal layer reflecting the light. Accordingly, the light generated from the organic emission layer 172 is reflected by the common electrode 173 and transmits through the pixel electrode 171 and the flexible substrate 10 and is emitted outside the flexible substrate 10. That is, the cubic display device 100 emits the light toward the outside of the polyhedron thereby displaying a predetermined image.

As described above, a plurality of pixels are continuously located throughout the plurality of flattened portions 11a-11f and the plurality of bending portions 12. Accordingly, the cubic display device 100 may display an image on the bending portion 12 as well as the flattened portions 11a-11f, such that a non-light emitting region of the polyhedron may be reduced or minimized, and such that one connected or continuous image may be displayed through the plurality of flattened portions 11a-11f and the plurality of bending portions 12.

A barrier layer 15 is positioned between the flexible substrate 10 and the thin film transistor layer 16, and may be formed of a deposition layer of silicon oxide and silicon nitride, thereby functioning to suppress diffusion of foreign particles included in the flexible substrate 10 into the thin film transistor layer 16. Also, a thin film encapsulation layer 18 is located on the organic light emitting diode (OLED) layer 17.

The thin film encapsulation layer 18 may be formed of a plurality of layers by alternately layering organic layers and inorganic layers. Each organic layer is formed of a polymer, and may be a single layer of a deposition layer including at least one of polyethylene terephthalate, a polyimide, a polycarbonate, an epoxy, polyethylene, and a polyacrylate. The inorganic layer includes a single layer of a deposition layer including at least one of a metal oxide and a metal nitride. For example, the inorganic layer may include one of SiNx, Al₂O₃, SiO₂, and TiO₂. Of the layers of the thin film encapsulation layer 18, a highest layer, which is exposed to the outside, may be formed of the inorganic layer to reduce or prevent vapor permeation into the organic light emitting diode (OLED) layer 17.

The flexible substrate 10 includes bonding portions 13 formed at at least one edge of the flattened portions 11a-11f. The bonding portions 13 are regions that overlap respective ones of the flattened portions 11a-11f when constructing the polyhedron. The bonding portions do not include pixels, and are configured to overlap the inside of the flattened portions 11a-11f as to not be exposed to the outside of the constructed polyhedron. Accordingly, the flexible substrate 10 can affix respective ones of the flattened portions 11a-11f by using respective ones of the bonding portions 13, thereby forming the integrated polyhedron. The bending portions 12 are also positioned between respective ones of the flattened portions 11a-11f and the bonding portions 13.

The scan drivers 20a-20c and the data drivers 30a-30c are formed on the inner surface of the flexible substrate 10 to be positioned at the surface intended to face toward the inside of the polyhedron. Also, at least one of the scan drivers 20a-20c and the data drivers 30a-30c is formed on the bonding portions 13, thereby being positioned to overlap the inside of the flattened portions 11a-11f. Further, at least one of the scan drivers 20a-20c and the data drivers 30a-30c formed on the bonding portions 13 is not visible when viewing the exterior of the polyhedron, such that the non-light emitting region of the polyhedron may be reduced or minimized.

In FIG. 2, the scan drivers 20a-20c are positioned on flattened portions 11a-11c among the plurality of flattened portions 11a-11f, and the data drivers 30a-30c are positioned on three of the bonding portions 13 that adjacent to the three flattened portions 11a-11c. In FIG. 2, the positions of the scan drivers 20a-20c and the data drivers 30a-30c may be exchanged. The number and positions of the scan drivers 20a-20c and the data drivers 30a-30c are not limited to the shown example, and may be variously changed.

The scan drivers 20a-20c and the data drivers 30-30c are electrically coupled to a plurality of pixels through a plurality of signal lines, thereby enabling supply of scan signals and data signals to the plurality of pixels.

In other embodiments of the present invention, the scan drivers 20a-20c and the data drivers 30a-30c may supply the scan signals and the data signals to the plurality of pixels wirelessly. For this, short distance wireless communication may be appropriately applied to the scan drivers 20a-20c, the data drivers 30a-30c, and the plurality of pixels. In such embodiments, a plurality of signal lines may be omitted such that spatial limitation is reduced and such that the expansion of the non-light emitting region of the polyhedron due to the signal lines may be prevented.

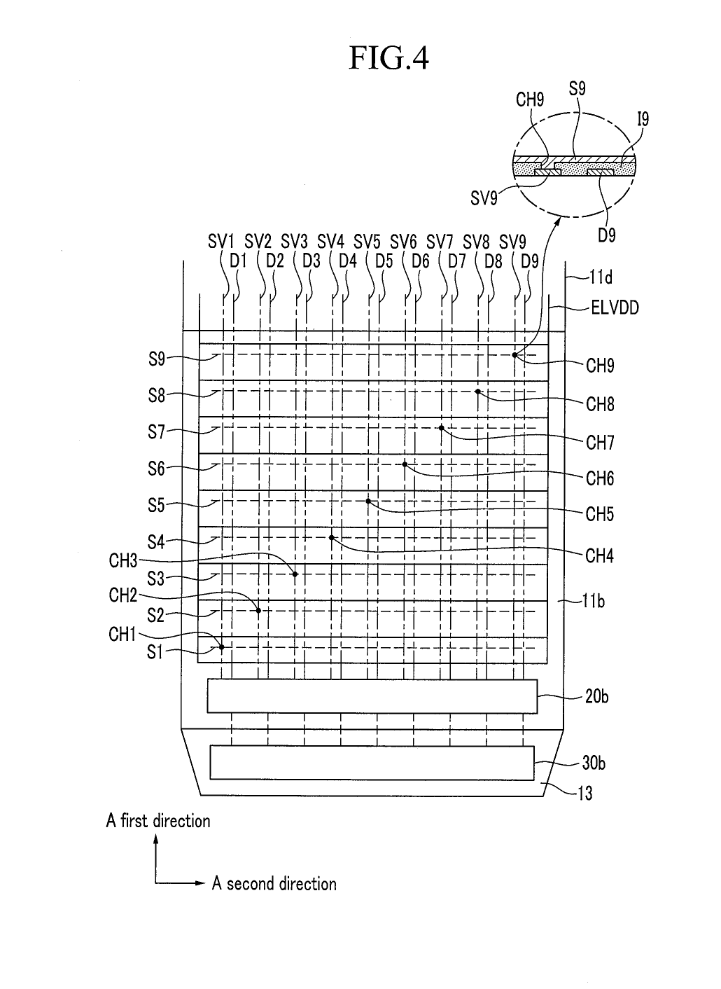

FIG. 4 is an enlarged partial view of the flexible substrate of the embodiment shown in FIG. 2. Referring to FIG. 2 and FIG. 4, respective ones of the scan drivers 20a-20c and the data drivers 30a-30c may be located in parallel. For example, the data drivers 30a-30c may be positioned at the partial bonding portions 13, and the scan drivers 20a-20c may be positioned parallel to the data drivers 30a-30c in the partial flattened portions 11a-11c neighboring the partial bonding portions 13.

In the present embodiment, the scan drivers 20a-20c and the data drivers 30a-30c may be located close to one edge of the flexible substrate 10 such that the plurality of pixels may be continuously formed throughout the remaining region except for a portion where the scan driver 20a-20c among the plurality of flattened portions 11a-11f and the plurality of bending portions 12 are formed. Accordingly, the cubic display device 100 may display one connected/continuous image on the polyhedron.

Generally, scan signal lines and data signal lines are crossed such that the scan driver and the data driver are perpendicular to each other. However, in the cubic display device 100 of the present exemplary embodiment, the scan drivers 20a-20c and the data drivers 30a-30c are located in parallel such that it is not necessary to control the direction of the signal lines (e.g., to have the signal lines cross).

Referring to FIG. 4, one surface of the flexible substrate 10 is coupled to the data driver 30b, a plurality of data signal lines D1-D9, which are formed along the first direction, and the scan driver 20b are coupled, and a plurality of first scan signal lines SV1-SV9, which are also formed along the first direction, and a plurality of second scan signal lines S1-S9, which are formed along the second direction crossing the first direction, may be formed. The first scan signal lines SV1-SV9 are respectively electrically coupled to the second scan signal lines S1-S9, and one pixel is in each region where the respective second scan signal lines S1-S9 and data signal lines D1-D9 cross.

The data signal lines D1-D9 and the first scan signal lines SV1-SV9 are formed with a first wire layer, and the second scan signal lines S1-S9 are formed with a second wire layer. Also, an insulating layer 19 is located between the first wire layer and the second wire layer, and has via holes CH1-CH9 at positions where the first scan signal lines SV1-SV9 cross the second scan signal lines S1-S9 corresponding thereto. The via holes CH1-CH9 are filled with a conducting material to electrically couple respective ones of the first scan signal lines SV1-SV9 and the second scan signal lines S1-S9 corresponding thereto.

Accordingly, the scan signal generated in the scan driver 20b is transmitted to a plurality of pixels along the second direction through the second scan signal lines S1-S9, and the data signal generated in the data driver 30b is transmitted to a plurality of pixels along the first direction through a plurality of data signal lines D1-D9. Also, a power source voltage wire ELVDD to transmit a pixel voltage to each pixel is formed at one surface of the flexible substrate 10.

Referring to FIG. 2, the scan drivers 20a-20c and the data drivers 30a-30c are not formed for each of the flattened portions 11a-11f, but may be located to control at least one of the flattened portions 11a-11f.

For example, the six flattened portions 11a-11f shown in FIG. 2 may be referred to as the first flattened portion to the sixth flattened portion 11a-11f, and the first scan driver 20a, the second scan driver 20b, and the third scan driver 20c are respectively positioned at the first flattened portion 11a, the second flattened portion 11 b, and the third flattened portion 11c. Also, the first data driver 30a, the second data driver 30b, and the third data driver 30c are respectively positioned at three of the bonding portions 13 neighboring the first flattened portion to the third flattened portion 11a-11c.

The first scan driver 20a and the first data driver 30a supply the signal to the pixels formed in the first flattened portion 11a, and the third scan driver 20c and the third data driver 30c supply the signal to the pixels formed in the third flattened portion 11c. Also, the signal lines of the second flattened portion 11b are elongated to the fourth flattened portion 11d, the fifth flattened portion 11e, and the sixth flattened portion 11f. Accordingly, the second scan driver 20b and the second data driver 30b supply the signal to the pixels positioned at the second, fourth, fifth, and sixth flattened portions 11b, 11d, 11e, and 11f.

Referring to FIG. 1 to FIG. 3, the cubic display device 100 of the present exemplary embodiment includes a plurality of rigid substrates 40 at respective locations corresponding to the plurality of flattened portions 11a-11f. Rigid substrates 40 are respectively positioned outside the flattened portions 11a-11f, and may be formed with a transparent glass material. A transparent bonding layer 41 is between the flexible substrate 10 and the rigid substrate 40. The size of the rigid substrate 40 may be the same as the size of the flattened portions 11a-11f.

The flexible substrate 10 is relatively thin such that it may potentially be bent or deformed by heat and pressure applied during the manufacturing process when forming the driving circuit and the organic light emitting diode (OLED) L1 on the flexible substrate 10. Also, since the flexible substrate 10 is relatively ineffective against moisture penetration, although the barrier layer 15 is formed on the inner surface, external moisture may penetrate into the driving circuit and the organic light emitting diode (OLED) L1 and potentially deteriorate the characteristics thereof.

In an initial manufacturing step of the cubic display device 100, the rigid substrate 40 is manufactured of an integrated substrate having a larger area than the flexible substrate 10. Also, after the flexible substrate 10 is affixed to the rigid substrate 40, the flexible substrate 10 is inserted into (e.g., used during) the manufacturing process of the driving circuit and the organic light emitting diode (OLED) L1. In the manufacturing process, the flexible substrate 10 is supported by the rigid substrate 40 to maintain a flat state such that bending or deformation that may be generated during the manufacturing process may be reduced or prevented altogether.

The rigid substrate 40 is selectively removed (e.g., portions of the rigid substrate 40 are removed) corresponding to a plurality of bending portions 12 after the driving circuit and the organic light emitting diode (OLED) L1 are formed on the flexible substrate 10 to remain on the outside surface of the flattened portions 11a-11f. As an example, a laser cutting device may be used in a process of cutting and removing the rigid substrate 40.

Moisture penetration into the rigid substrate 40 is low, such that moisture penetration into the driving circuit, the organic light emitting diode (OLED) L1, and the scan drivers 20a-20c may be reduced or prevented. Accordingly, the cubic display device 100 reduces or minimizes changes of the electrical characteristics of the driving circuit, the organic light emitting diode (OLED) L1, and the scan drivers 20a-20c, thereby increasing the display quality and extending the usage life-span.

Also, for the cubic display device 100, the moisture penetration is reduced or prevented by the rigid substrate 40 such that the barrier layer 15 may be made thin or omitted altogether, and the organic light emitting diode (OLED) layer 17 is sealed by the integrally connected polyhedral structure such that the thin film encapsulation layer 18 may also be made thin or omitted altogether. As described above, the cubic display device 100 increases product reliability with respect to the display characteristics and the life-span of cubic display device 100.

In other embodiments of the present invention, the scan drivers 20a-20c may be positioned at the flattened portions 11a-11c attached with the rigid substrate 40, or may be positioned at respective ones of the bending portions 12 or the bonding portions 13 as well as the flattened portions 11a-11c.

FIG. 5 is an enlarged cross-sectional view of a cubic display device according to a second exemplary embodiment of the present invention, and is shown in a state in which a flexible substrate is unfolded. The cubic display device according to the second exemplary embodiment has the same components as the first exemplary embodiment, although the positions of the scan drivers 20a-20c in the second embodiment are different than those of the first embodiment.

Referring to FIG. 5, in the second exemplary embodiment, the scan drivers 20a-20c are positioned at one of the bending portions 12 between the flattened portions 11a-11c and one of the bonding portions 13. In the embodiment shown in FIG. 2, the image may not be displayed in the region where the scan drivers 20a-20c are located among the flattened portions 11a-11c. However, in the embodiment shown in FIG. 5, the image may be displayed on the entire flattened portions 11a-11c. Accordingly, the non-light emitting region of the polyhedron may be effectively reduced.

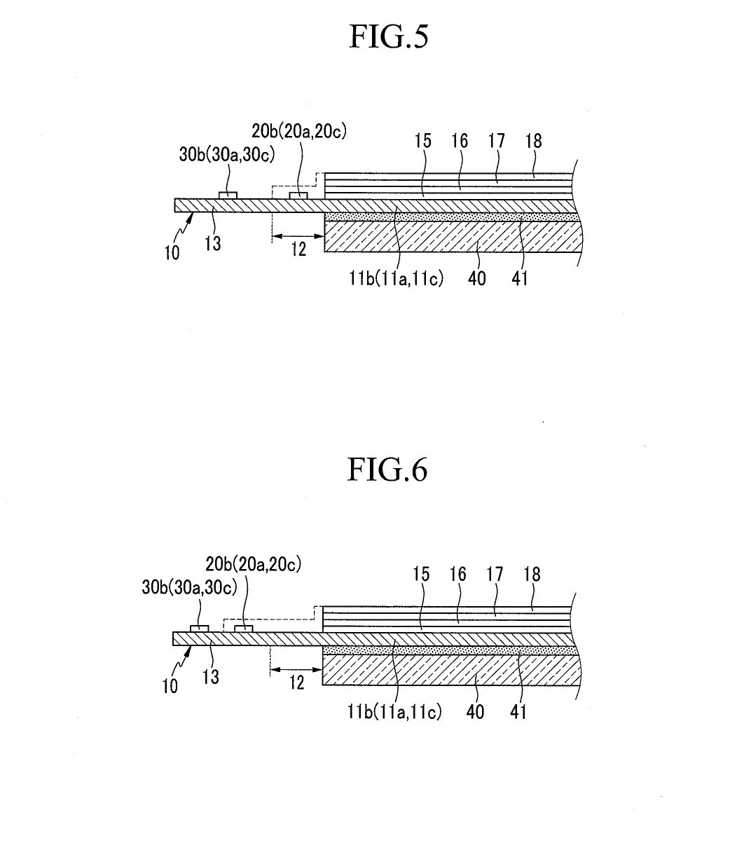

FIG. 6 is an enlarged cross-sectional view of a cubic display device according to a third exemplary embodiment, and is shown in a state in which a flexible substrate is unfolded. The cubic display device according to the third exemplary embodiment has the same components as the first exemplary embodiment, but the positions of the scan drivers 20a-20c are different from those of the first embodiment.

Referring to FIG. 6, in the third exemplary embodiment, the scan drivers 20a-20c and the data drivers 30a-30c are positioned at one of the bonding portions 13. The scan drivers 20a-20c and the data drivers 30a-30c are fixed to the bonding portions 13 overlapping the inside of the flattened portions 11a-11c to be unseen outside the polyhedron. In the third exemplary embodiment, the image is also displayed on the entire flattened portions 11a-11c such that the non-light emitting region of the polyhedron may be effectively reduced.

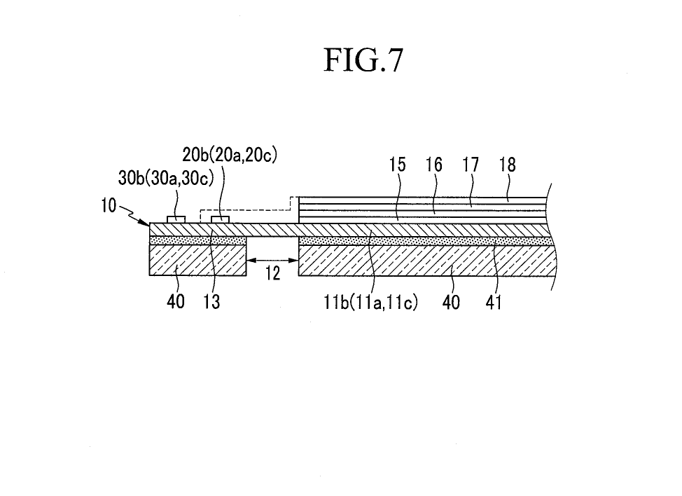

FIG. 7 is an enlarged cross-sectional view of a cubic display device, according to a fourth exemplary embodiment, shown in a state in which a flexible substrate is unfolded. The cubic display device of the fourth exemplary embodiment has the same components as the third exemplary embodiment. However, the rigid substrate 40 is positioned at one surface of the flexible substrate 10 corresponding to one of the bonding portions 13.

Referring to FIG. 7, a rigid substrate 40 is additionally positioned outside the bonding portion 13 and is mounted with the scan driver 20a-20c and the data driver 30a-30c, and the transparent bonding layer 41 is formed between the bonding portion 13 and the rigid substrate 40. The rigid substrate 40 attached to the bonding portion 13 reduces or prevents moisture penetration into the scan drivers 20a-20c and the data drivers 30a-30c, such that the characteristic change of the scan drivers 20a-20c and the data drivers 30a-30c may be reduced or minimized.

In the cubic display devices of the first exemplary embodiment to the fourth exemplary embodiment, the thin film encapsulation layer 18 may also be formed on the scan drivers 20a-20c. That is, the thin film encapsulation layer 18 may be formed wider than the thin film transistor layer 16 to cover the scan drivers 20a-20c as well as the organic light emitting diode (OLED) layer 17. Accordingly, moisture penetration for the scan drivers 20a-20c may be further reduced. In FIG. 3 and FIG. 5 to FIG. 7, the thin film encapsulation layer 18 covering the scan drivers 20a-20c is indicated by a dotted line.

In the cubic display device of the first exemplary embodiment to the fourth exemplary embodiment, the positions of the scan drivers 20a-20c and the data drivers 30a-30c may be exchanged.

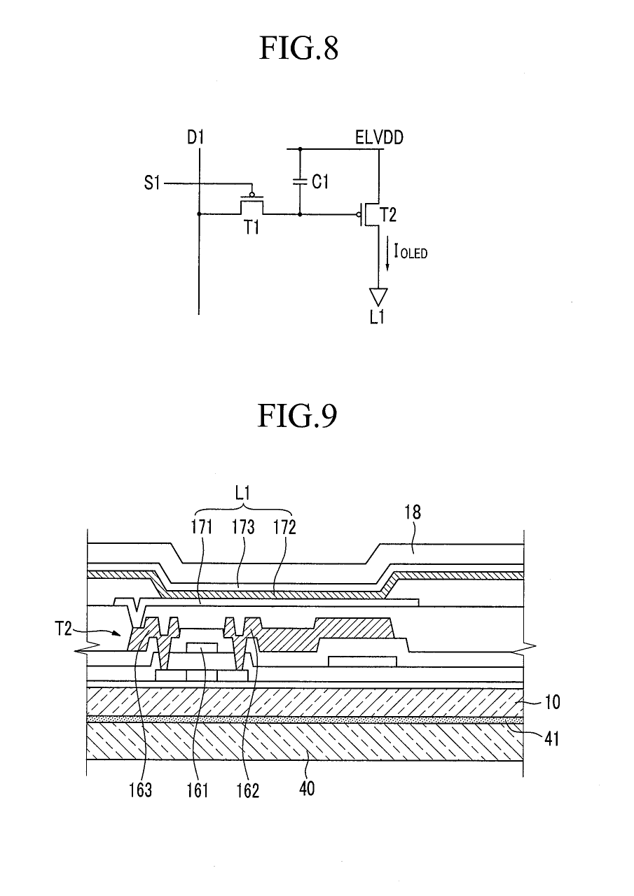

FIG. 8 is a view of a pixel circuit of the cubic display device of the embodiment shown in FIG. 1, and FIG. 9 is a partial enlarged cross-sectional view of the cubic display device of the embodiment shown in FIG. 3.

Referring to FIG. 8 and FIG. 9, the pixel includes the organic light emitting diode (OLED) L1 and driving circuits T1, T2, and C1. The organic light emitting diode (OLED) L1 includes the pixel electrode 171, the organic emission layer 172, and the common electrode 173. The driving circuits T1, T2, and C1 include at least two thin film transistors (a switching transistor T1 and a driving transistor T2) and at least one capacitor C1.

The switching transistor T1 is coupled to the second scan signal line S1 and the data signal line D1, and the data voltage input from the data signal line D1 is transmitted to the driving transistor T2 according to a switching voltage input to the second scan signal line S1. The capacitor C1 is coupled to the switching transistor T1 and the power source voltage wire ELVDD, and stores a voltage corresponding to a difference between the voltage transmitted from the switching transistor T1 and the voltage supplied to the power source voltage wire ELVDD.

The driving transistor T2 is coupled to the power source voltage wire ELVDD and the capacitor C1 to supply an output current (I_{OLED}) in proportion to a square of a difference between the voltage stored to the capacitor C1 and the threshold voltage to the organic light emitting diode (OLED) L1, and the organic light emitting diode (OLED) L1 emits light with intensity that is proportional to the output current. The driving transistor T2 includes a gate electrode 161 and source/drain electrodes 162 and 163, and the pixel electrode 171 may be coupled to the drain electrode 163 of the driving transistor T2.

The pixel circuit shown in FIG. 8 and the cross-sectional structure of the cubic display device shown in FIG. 9 are only exemplary, and the cubic display device of embodiments of the present invention is not limited thereto, and may be variously changed.

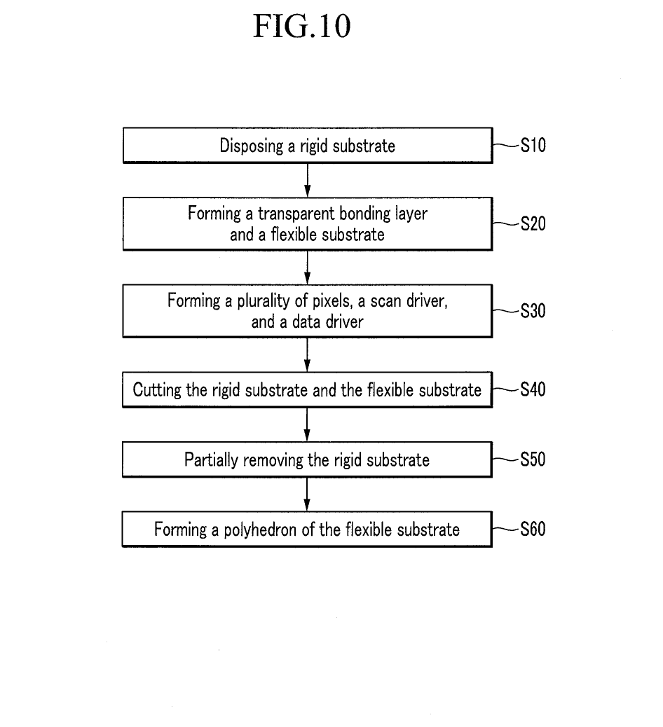

FIG. 10 is a process flowchart of a manufacturing method of a cubic display device according to an exemplary embodiment. Referring to FIG. 10, a manufacturing method of the cubic display device includes a first step S10 of disposing, or forming or obtaining, a rigid substrate, a second step S20 of forming a transparent bonding layer and a flexible substrate on the rigid substrate, and a third step S30 of forming a plurality of pixels, a scan driver, and a data driver on the flexible substrate. The manufacturing method of the cubic display device further includes a fourth step S40 of cutting the rigid substrate and the flexible substrate to have a shape of the polyhedron in an unfolded form, a fifth step S50 of removing a portion(s) of the rigid substrate to maintain the rigid substrate at the outer surface of the flattened portion, and a sixth step S60 of bending and folding the flexible substrate to form the polyhedron.

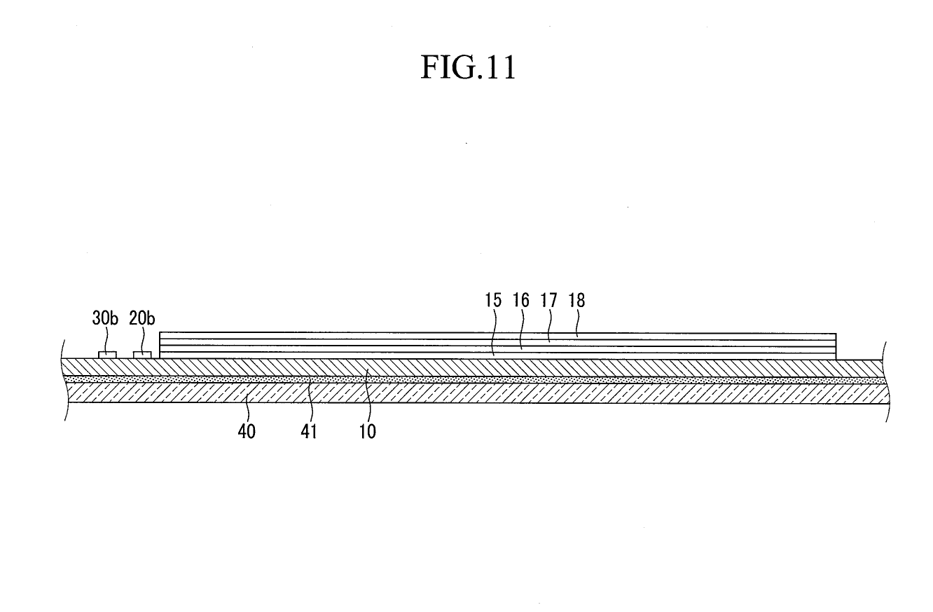

FIG. 11 is a cross-sectional view of the cubic display device at the third step S30 of the embodiment described in FIG. 10. Referring to FIG. 11, the rigid substrate 40 is formed on a transparent glass material in the first step S10, and the flexible substrate 10 may be made of a plastic material, such as a polyimide, in the second step S20. In the third step S30, a plurality of pixels, the scan driver 20b, and the data driver 30b are formed on the flexible substrate 10.

The plurality of pixels respectively include at least two thin film transistors, one capacitor, and one organic light emitting diode (OLED). In FIG. 11, a plurality of thin film transistors are schematically shown as one thin film transistor layer 16, and a plurality of organic light emitting diodes (OLED) are schematically shown as one organic light emitting diode (OLED) layer 17.

A barrier layer 15 formed of an inorganic material, such as silicon oxide or silicon nitride, is formed between the flexible substrate 10 and the thin film transistor layer 16. Also, a thin film encapsulation layer 18 covering and encapsulating a plurality of pixels is positioned on the organic light emitting diode (OLED) layer 17. The thin film encapsulation layer 18 may be formed to cover the scan drivers 20a-20c. The scan driver 20b and the data driver 30b may be formed directly on the flexible substrate 10, or may be formed with a separate driving IC chip to then be installed to (e.g., affixed to) the flexible substrate 10.

In the third step S30, the flexible substrate 10 is supported by the rigid substrate 40 to thereby be maintained in a flat state. Accordingly, in a process of forming a plurality of pixels on the flexible substrate 10, although heat and pressure are applied to the flexible substrate 10, bending or deformation of the flexible substrate 10 due thereto may be reduced or prevented.

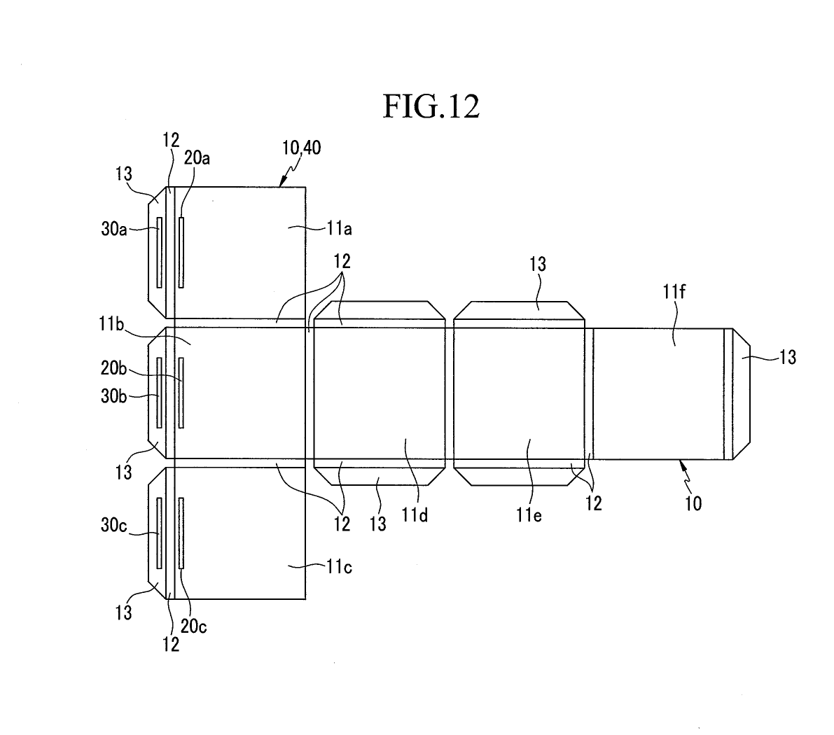

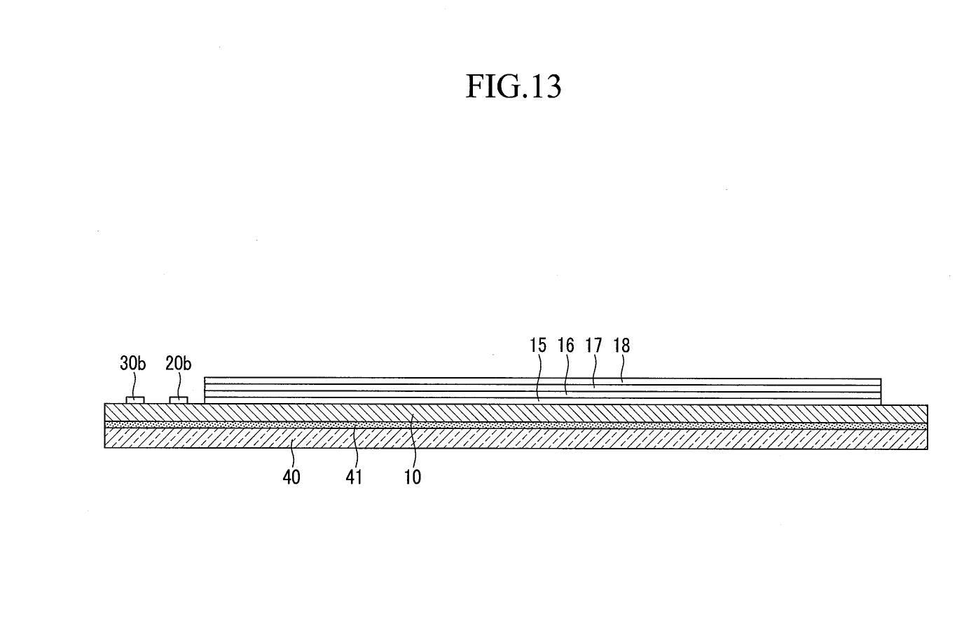

FIG. 12 and FIG. 13 are a top view and a cross-sectional view of the cubic display device of the embodiment of FIG. 10 shown in the fourth step S40. Referring to FIG. 12 and FIG. 13, in the fourth step S40, the rigid substrate 40 and the flexible substrate 10 are cut to have the unfolded shape of the polyhedron. That is, in the fourth step S40, the rigid substrate 40 and the flexible substrate 10 are cut to include a plurality of flattened portions 11a-11f, bending portions 12 (in the fourth step S40, in the flat state) between two neighboring ones of the flattened portions 11a-11f, and a plurality of bonding portions 13 each formed at at least one edge of respective ones of the flattened portions 11a-11f.

The rigid substrate 40 of the first step S10 and the flexible substrate 10 of the second step S20 may be formed with a size and shape corresponding to the polyhedron in an unfolded shape. That is, the rigid substrate 40 of the first step S10 and the flexible substrate 10 of the second step S20 are manufactured of a mother substrate shape, and are divided into a plurality of unfolded portions through a cutting process of the fourth step S40.

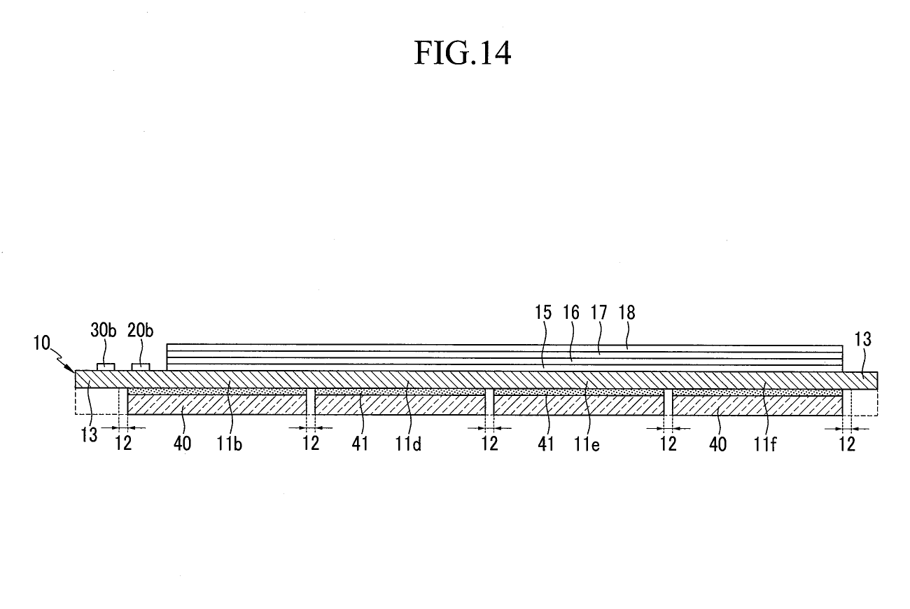

FIG. 14 is a cross-sectional view of the cubic display device of FIG. 10 shown in the fifth step S50. Referring to FIG. 14, in the fifth step S50, portions of the rigid substrate 40 corresponding to a plurality of bending portions 12 and a plurality of bonding portions 13 are cut and removed. Accordingly, the rigid substrate 40 is divided into several remaining portions, and a plurality of rigid substrates 40 are selectively maintained at only the outer surface of the flattened portions 11a-11f. The laser cutting device may be used in the cutting process of the fourth step S40 and the fifth step S50, and the portion(s) of the transparent bonding layer 41 is removed along with the rigid substrate 40 in the fifth step S50.

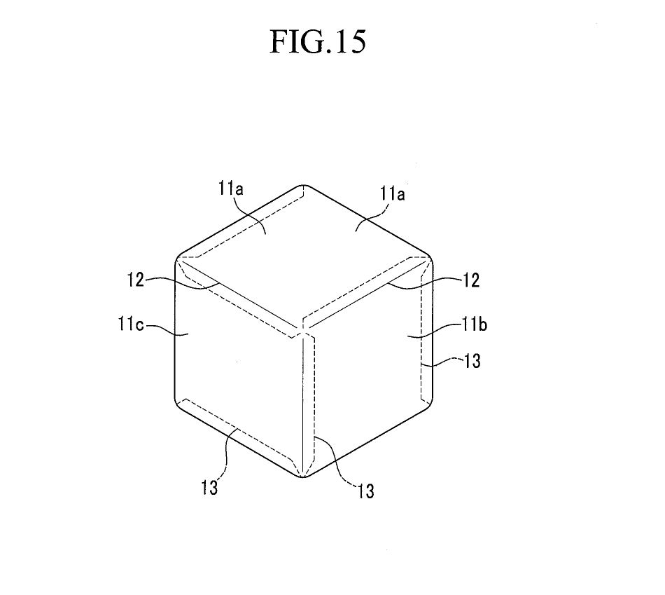

FIG. 15 is a perspective view of the cubic display device of FIG. 10 in the sixth step S60. Referring to FIG. 14 and FIG. 15, as the rigid substrate 40 is partially removed in the fifth step S50, the bending portion 12 of the flexible substrate 10 may be bent, and the bonding portion 13 may be folded from the flattened portions 11a-11f to thereby overlap the flattened portions 11a-11f. Accordingly, in the sixth step S60, the flexible substrate 10 is bent in the bending portion 12 and the bonding portion 13 is folded and is attached on the inner surface of the flattened portions 11a-11f, thereby forming the polyhedron. In FIG. 15, for convenience, the rigid substrate is omitted.

in the manufacturing method of the described cubic display device 100, although the scan drivers 20a-20c are described as being positioned at the flattened portions 11a-11c, the scan drivers 20a-20c may alternatively be positioned at one or more of the bending portions 12 and the bonding portions 13. Also, the rigid substrate 40 may be positioned at one surface of the flexible substrate 10 corresponding to the bonding portion 13 mounted with the scan drivers 20a-20c and the data drivers 30a-30c.

Although the described embodiments of the present invention refer to a cubic display device, it should be understood that other embodiments of the present invention may include a multisided display device that is not cubic (e.g., the display device may be of the shape of a tetrahedron).

While this disclosure has been described in connection with what is presently considered to be practical exemplary embodiments of the present invention, it is to be understood that the present invention is not limited to the disclosed embodiments, but, on the contrary, is intended to cover various modifications and equivalent arrangements included within the spirit and scope of the appended claims, and their equivalents.

Description of Some of the Reference Characters

| | |
|---|---|
| 100: cubic display device | 10: flexible substrate |
| 11a-11f: flattened portions | 12: bending portions |
| 13: bonding portions | 20a-20c: scan drivers |
| 30a-30c: data drivers | 40: rigid substrate |
| 41: transparent bonding layer | |

What is claimed is:

1. A multisided display device comprising:
a flexible substrate configured to have a shape of a polyhedron and comprising:
a plurality of flattened portions;
a plurality of bending portions;
a first surface having a plurality of pixels thereon; and
a second surface opposite the first surface;
a plurality of rigid substrates corresponding to the plurality of flattened portions and positioned at the second surface of the flexible substrate;
a scan driver for supplying a scan signal to the plurality of pixels; and
a data driver for supplying a data signal to the plurality of pixels.

2. The multisided display device of claim 1, wherein the plurality of flattened portions and the plurality of bending portions collectively have the shape of the polyhedron in an unfolded state, and
wherein the flexible substrate is configured to have the shape of the polyhedron by bending the plurality of bending portions.

3. The multisided display device of claim 2, wherein the first surface of the flexible substrate is configured to be toward an inside of the polyhedron, and
wherein the pixels are at areas corresponding to the flattened portions and to the bending portions.

4. The multisided display device of claim 3, wherein each of the pixels comprise:
a transparent pixel electrode;
an organic emission layer on the pixel electrode; and
a reflective common electrode on the organic emission layer, and
wherein the pixels are configured to emit light toward the flexible substrate.

5. The multisided display device of claim 3, further comprising:
a barrier layer between the flexible substrate and the pixels; and
a thin film encapsulation layer on the pixels.

6. The multisided display device of claim 5, wherein the thin film encapsulation layer covers the scan driver or the data driver.

7. The multisided display device of claim 2, wherein the flexible substrate further comprises a bonding portion at an edge of a first one of the flattened portions, and
wherein the bonding portion is configured to overlap and be affixed to an inner surface of a second one of the flattened portions.

8. The multisided display device of claim 7, wherein the scan driver and the data driver are at the first surface of the flexible substrate, and are configured to respectively supply the scan signal and the data signal to at least one of the flattened portions.

9. The multisided display device of claim 8, wherein one of the scan driver or the data driver is on the bonding portion, and wherein an other one of the scan driver or the data driver is on one of the flattened portions or one of the bending portions.

10. The multisided display device of claim 8, wherein the scan driver and the data driver are on an area of the bonding portion, and
wherein the bonding portion is at a location corresponding to the rigid substrate.

11. The multisided display device of claim 8, further comprising:
a plurality of first scan signal lines arranged in a first direction;
a plurality of second scan signal lines arranged in a second direction crossing the first direction; and
a plurality of data signal lines arranged in the first direction,
wherein the first scan signal lines, the second scan signal lines, and the data signal lines are between the data driver and the pixels,
wherein the scan driver and the data driver are arranged in parallel.

12. The multisided display device of claim 11, further comprising an insulating layer between the first scan signal lines and the second scan signal lines,
wherein the second scan signal lines are electrically coupled to respective ones of the first scan signal lines through via holes in the insulating layer.

13. The multisided display device of claim 1, further comprising a transparent bonding layer between the flexible substrate and the rigid substrate,
wherein the second surface of the flexible substrate is toward an outside of the polyhedron.

14. A method manufacturing a multisided display device, the method comprising:
providing a rigid substrate;
forming a transparent bonding layer and a flexible substrate on the rigid substrate;
forming a plurality of pixels, a scan driver, and a data driver on the flexible substrate;
cutting the rigid substrate and the flexible substrate to comprise a plurality of flattened portions, a plurality of bending portions, and a plurality of bonding portions;
removing portions of the rigid substrate such that remaining portions of the rigid substrate are at an outer surface of respective ones of the flattened portions; and
bending the bending portions to form a polyhedron.

15. The method of claim 14, wherein the removing the portions of the rigid substrate causes the rigid substrate and the flexible substrate to be in a shape of the polyhedron in an unfolded state.

16. The method of claim 14, wherein the plurality of pixels, the scan driver, and the data driver are formed at a first surface configured to face toward an inside of the polyhedron.

17. The method of claim 14, further comprising:
forming a barrier layer between the flexible substrate and the plurality of pixels; and
forming a thin film encapsulation layer on the pixels,
wherein the pixels are at the flattened portions and the bending portions.

18. The method of claim 14, wherein one of the scan driver or the data driver is at one of the bonding portions, and
wherein an other one of the scan driver or the data driver is at one of the flattened portions or one of the bending portions.

19. The method of claim 14, wherein the scan driver and the data driver are at one of the bonding portions, and
wherein the removing the portions of the rigid substrate causes the remaining portions of the rigid substrate to be at an outer surface of the bonding portions.

20. The method of claim 14, further comprising:
folding the bonding portion inside one of the flattened portions; and
bonding the bonding portion to the one of the flattened portions.
